(19) United States
(12) Patent Application Publication
(10) Pub. No.: US 2026/0088772 A1
(43) Pub. Date: Mar. 26, 2026

(54) POWER-EFFICIENT DIGITAL POWER AMPLIFIERS

(71) Applicant: Morse Micro Pty. Ltd., Surry Hills NSW (AU)

(72) Inventor: Justin Penfold, Cambridge (GB)

(21) Appl. No.: 19/263,334

(22) Filed: Jul. 8, 2025

(30) Foreign Application Priority Data
Sep. 26, 2024 (AU) 2024903101

(51) Int. Cl. H03F 1/02; H03F 1/56; H03F 3/24

(52) U.S. Cl. CPC H03F 1/0288; H03F 1/56; H03F 3/245; H03F 2200/387; H03F 2200/451

(57) ABSTRACT

A switch capacitor power amplifier includes at least two inverter and capacitor arrays and a transformer. The inverter and capacitor arrays configured to be driven by a respective digital clock signal and a digital amplitude control signal. Each inverter drives a unit capacitor in the inverter and capacitor arrays. The transformer having a primary coil connected to the inverter and capacitor arrays and a secondary coil configured to deliver a Radio Frequency output signal. Each inverter and capacitor array is selectively activated based on the digital amplitude control signal, such that all inverters of a first inverter and capacitor array are activated before any of the inverters of a second inverter and capacitor array.

### CROSS-REFERENCE TO RELATED APPLICATIONS

This application claims the benefit of Australian Provisional Patent Application No. 2024903101, filed Sep. 26, 2024, which is hereby incorporated by reference, in its entirety and for all purposes.

### FIELD OF THE INVENTION

The present disclosure generally relates to circuit design. Specifically, aspects of the present disclosure are related to digital power amplifiers.

### BACKGROUND

An RF Power Amplifier (PA) is a critical component of any radio system, as it is responsible for delivering the output RF power required for wireless transmission. Due to its role in converting Direct Current (DC) supply power into RF output power, the PA typically accounts for a substantial portion of the overall power consumption of the radio system. Consequently, achieving high power conversion efficiency in the PA is of paramount importance. Traditionally, RF power amplifiers are designed to achieve peak efficiency when operating at or near their maximum output power. However, this efficiency tends to degrade significantly when the output power is reduced, a condition referred to as power back-off. This presents a challenge in modern wireless communication systems, where variable power levels are frequently required.

Many contemporary wireless systems employ modulation schemes such as Orthogonal Frequency Division Multiplexing (OFDM), which are characterized by a high Peak-to-Average Power Ratio (PAPR). As a result, the PA operates in back-off conditions for the majority of its operating time, where its efficiency is substantially low. For example, Wi-Fi systems typically operate with PAPRs in the range of 8 to 12 dB, meaning that the average transmit power is often only around 10% of the peak power. Under these conditions, conventional power amplifiers operate inefficiently for most of the time.

A notable approach to improving back-off efficiency was proposed by W. H. Doherty in his publication titled “A New High-Efficiency Power Amplifier for Modulated Waves. ” The so-called Doherty amplifier architecture utilizes two separate power amplifiers in parallel: a main amplifier that operates across the power range and a boost amplifier that is activated only at higher output levels. By intelligently combining the outputs of these two amplifiers, the system can maintain higher efficiency over a wider dynamic range compared to a conventional single amplifier.

RF front ends architecture offers clear efficiency advantages, practical attempts to implement this technique in modern integrated PA designs, particularly in highly integrated RF front ends, have encountered significant challenges. These include difficulties in achieving precise phase and amplitude matching, maintaining linearity, and implementing the necessary load modulation in compact, monolithic form factors. As such, further improvements and alternative solutions remain a subject of ongoing research and development.

### SUMMARY

The following summary presents technical features relating to one or more aspects of disclosed herein and should not be considered as an extensive overview relating to all contemplated aspects. Accordingly, the following summary has the sole purpose to present certain concepts relating to one or more embodiments relating to packet detection disclosed herein in a simplified form to precede the detailed description presented below.

A Switch capacitor Power amplifier (ScPa) includes at least two inverter and capacitor arrays and a transformer. The inverter and capacitor arrays are configured to be driven by a respective digital clock signal and a digital amplitude control signal, where each inverter drives a unit capacitor in the inverter and capacitor arrays. A primary coil of the transformer connects to the inverter and capacitor arrays and a secondary coil is configured to deliver a Radio Frequency (RF) output signal. Each inverter and capacitor array is selectively activated based on the digital amplitude control signal, such that all inverters of a first inverter and capacitor array are activated before any of the inverters of a second inverter and capacitor array.

In some embodiments, the transformer is configured as a series resonant balun primary from two tightly coupled inductors, and the transformer primary inherently performs signal combination for the at least two inverter and capacitor arrays without requiring an external output combiner. Some embodiments of the inverter and capacitor arrays are activated in stages, such that the first inverter and capacitor array is fully driven before the second inverter and capacitor array is progressively enabled, producing multiple efficiency peaks over an RF output amplitude range.

The digital amplitude control signal may contain digital amplitude codes corresponding to In-phase (I) and Quadrature (Q) components, and the ScPa is configured to operate in a cartesian system. A lower half of the digital amplitude codes corresponding to I component is applied to the first inverter and capacitor array, while a lower half of the digital amplitude codes corresponding to Q component is applied to the second inverter and capacitor array, the upper halves of the respective digital amplitude codes are cross applied to the opposite array.

In some embodiments, each inverter and capacitor array is subdivided into two or four independent sections, forming multiple separate branches, each branch is independently controlled by segments of the digital amplitude codes corresponding to the I and Q components. Each inverter and capacitor array is controlled independently to allow subsequential activation within the array. For example, eight inverter and capacitor arrays are coupled via a quadruple-primary transformer composed of tightly coupled inductors, and each inverter and capacitor array corresponds to one-eighth of an amplitude code range for the digital amplitude control signal. Maximum power efficiency is achieved at amplitude settings corresponding to ⅛, ¼, ⅜, ½, ⅝, ¾, ⅞ and 1.

Each inverter and capacitor array forms a capacitive voltage divider, and an amplitude of the RF output signal is proportional to the number of active inverters. The inverter and capacitor arrays form a series resonant circuit with the transformer primary, tuned to a desired operating frequency. The ScPa generates high currents at the desired operating frequency and attenuates unwanted RF harmonics created by the digital clock signal. The high currents induced in the primary coil of the transformer is coupled to the secondary coil, and the high currents undergo impedance transformation.

Embodiments of inactive inverters in each inverter and capacitor array maintain impedance matching as the activated inverters. In some embodiments, the RF output signal is a single-ended signal suitable for directly driving a transmitting antenna. In another aspect, independent drive signals are applied to each end of the primary coil, allowing each of the inverter and capacitor arrays to function as a separate amplifier branch.

Other objects and advantages associated with the aspects disclosed herein will be apparent to those skilled in art based on the accompanying drawings and detailed description.

### BRIEF DESCRIPTION OF THE DRAWINGS

Illustrative aspects of the present application are described in detail below with reference to the following drawing figures:

FIG. 1 illustrates an embodiment of the digitally controlled ScPa receiving a digital amplitude control signal and digital clock signals in accordance with an embodiment of the present invention.

FIG. 2 illustrates an embodiment of a power amplifier with two inverter and capacitor arrays.

FIG. 3 shows power efficiency versus the RF output amplitude for a standard power amplifier and a ScPa with a combined scheme according to an embodiment of the present invention.

FIG. 4 illustrates an embodiment of the ScPa with two inverter and capacitor arrays driving by digital amplitude codes for I and Q components.

FIG. 5 is a cartesian constellation map showing efficiency peaks for the ScPa design in FIG. 4.

FIG. 6 illustrates an embodiment of the ScPa with four inverter and capacitor arrays driving by digital amplitude codes for I and Q components.

FIG. 7 shows power efficacy versus the RF output amplitude for a standard power amplifier and a ScPa with four-arrays combined scheme according to an embodiment of the present invention.

FIG. 8 is a cartesian constellation map showing efficiency peaks for the ScPa design in FIG. 6.

FIG. 9 illustrates an embodiment of the ScPa with eight inverter and capacitor arrays driving by digital amplitude codes for I and Q components.

FIG. 10 shows power efficacy versus the RF output amplitude for a standard power amplifier and a ScPa with eight-arrays combined scheme according to an embodiment of the present invention.

FIG. 11 is a cartesian constellation map showing efficiency peaks for the ScPa design in FIG. 9.

### DETAILED DESCRIPTION

Certain aspects and embodiments of this disclosure are provided below. Some of these embodiments may be applied independently and some of them may be applied in conjunction as would be apparent to those of skill in the art. In the following description, for the purposes of explanation, specific details are set forth to provide a thorough understanding of aspects of the application. However, it will be apparent that various embodiments may be practiced without these specific details. The following description of the embodiments will provide those skilled in the art with an enabling description for implementing an example aspect. Changes may be made in the function and arrangement of elements without departing from the spirit and scope of the application as set forth in the claims.

Attempts to implement Doherty amplifier architectures within modern integrated Power Amplifiers (PAs) have generally faced significant challenges. Chief among these is the requirement for a large and complex output combiner component, which must match consistently to the output impedances of the individual power amplifier branches. These output impedances often vary substantially with output power, complicating the design and limiting practical deployment in integrated circuits.

The Switched capacitor Power amplifier (ScPa) was developed in part to eliminate the need for a Digital-to-Analog Converter (DAC), enabling an entirely digital PA architecture. Digital power amplifiers are particularly well-suited for integration into Complementary Metal-Oxide-Semiconductor (CMOS) systems. Embodiments of the present invention apply the Doherty concept to a digitally controlled ScPa, leveraging the observed characteristic that the output impedance of an ScPa remains effectively constant across different gain settings. This key feature allows for a Doherty-like efficiency enhancement without the traditional drawbacks associated with impedance variation.

Importantly, the components inherently present in a standard ScPa implementation can be configured to act as the combiner required for a Doherty scheme, eliminating the need for additional large or complicated circuitry. In addition, when operating in a Cartesian system, the amplifier's control signals can be arranged to combine the In-phase (I) and Quadrature (Q) components efficiently, without the degradation in efficiency typically introduced by integrated mixers.

In some embodiments, a modification to the combiner arrangement that enables the power amplifier to achieve high efficiency not only at 6 dB back-off (as in classical Doherty designs) but also at 12 dB back-off, and at 18 dB back off, thereby improving efficiency across a wider range of output power levels.

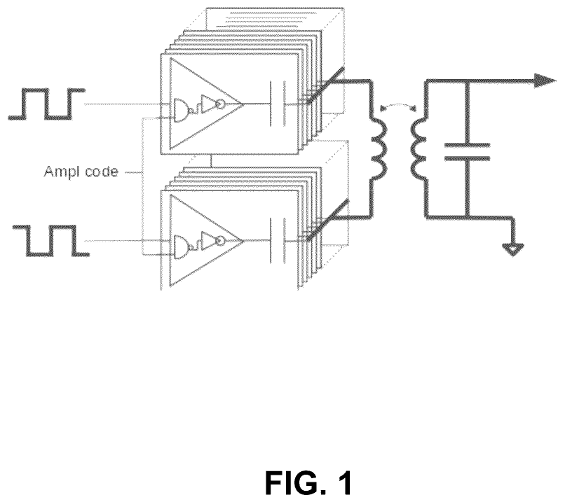

In certain embodiments, a digitally controlled ScPa comprises two arrays of CMOS inverters. FIG. 1 illustrates an embodiment of the digitally controlled ScPa receiving a digital amplitude control signal (ampl code) and respective digital clock signals composed of square waves. Each inverter drives a unit capacitor, and the capacitors from each array are connected to the primary inputs of an inductive transformer (balun). One inverter array is driven by a digital clock signal with a square wave, and the other by a digital clock signal with an anti-phase square wave, both at the desired RF output frequency. Within each array, only a subset of inverters is activated while the remaining inverters are held static based on a digital amplitude control signal. The resulting configuration functions as a capacitive divider, producing an output voltage amplitude proportional to the number of active inverters.

The complete differential inverter-capacitor-inductor circuit forms a series resonant circuit tuned to the desired operating frequency. This architecture generates high currents at the desired operating frequency and naturally attenuates unwanted RF harmonics created by the square-wave drive. The high current induced in the primary coil of the balun is coupled to the balun secondary coil, where it undergoes impedance transformation and is converted to a single-ended signal suitable for directly driving a transmitting antenna.

The balun primary coil provides the combination of these two inverter and capacitor arrays that are necessary for Doherty efficiency enhancement. One of the novel observations of the invention is that static (inactive) inverters have the same output impedance as active (clocked) ones, thus preserving the resonant properties of the circuit regardless of the digital amplitude code. Inactive inverters introduce capacitive loading and dissipate power, meaning efficiency degrades as more inverters are held static. Maximum efficiency is achieved when all inverters within an array are active.

Traditional ScPa designs employ differential drives across the balun primary using varying amplitudes from the two inverter and capacitor arrays. Embodiments of the invention recognizes that a well-designed transformer with high common-mode rejection can eliminate the need for strict differential driving. Instead, independent drive signals can be applied to each end of the primary coil, allowing each inverter and capacitor array to function as a separate amplifier branch in a Doherty configuration. The combining action inherent to the transformer primary thus fulfills the Doherty function. Since the output impedance of each inverter and capacitor array remains constant, amplitude signals from each inverter and capacitor array combine linearly, ensuring signal integrity.

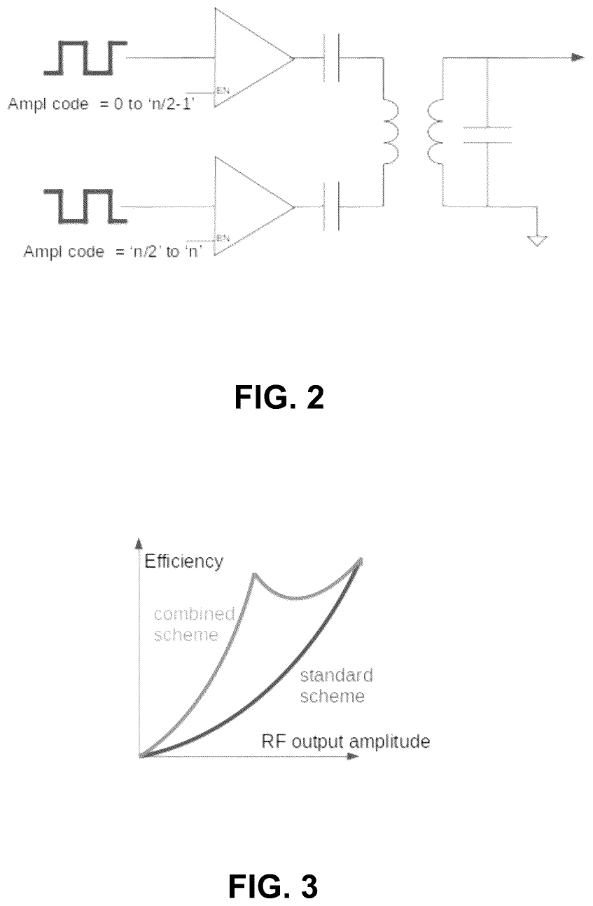

FIG. 2 illustrates an embodiment of a power amplifier with two inverter and capacitor arrays. This embodiment is applicable to a non-Cartesian system, where a lower half of the digital amplitude code (0 to n/2−1) drives the first inverter and capacitor array while an upper half of the digital amplitude code (n/2 to n) drives the second array. The first inverter and capacitor array is activated while the second inverter and capacitor array remains static for lower amplitude codes (i.e. when the upper half of the digital amplitude code is zero). Once the first array is fully driven and therefore operating maximum efficiency, the second array is activated by the upper half of the digital amplitude code. FIG. 3 is a graph illustrating the power amplifier efficiency with respect to the RF output amplitudes comparing between a standard scheme and an embodiment of the combined scheme. This staged activation yields two efficiency peaks: one when only the first array is fully driven and another when both arrays are fully driven as shown in FIG. 3.

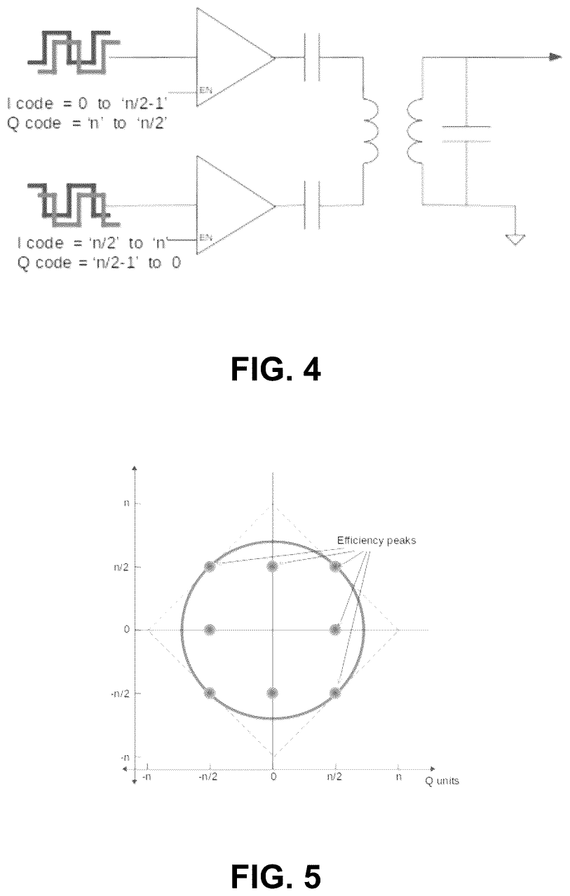

FIG. 4 shows an embodiment of the cartesian ScPa configured to achieve enhanced efficiency. In cartesian implementations, similar principles are applied using I and Q amplitude codes. For instance, the lower half of the I amplitude code is applied to the first inverter and capacitor array and the lower half of the Q amplitude code is applied to the second inverter and capacitor array. The upper half of each I or Q amplitude code is then cross applied to the opposite array. This arrangement enables multiple points within the cartesian constellation to benefit from peak efficiency, as illustrated in FIG. 5. FIG. 5 illustrates the cartesian constellation map representing the output characteristics of a digitally controlled ScPa. Unlike traditional ScPa designs, which typically exhibit peak efficiency at only a single amplitude level, this embodiment demonstrates multiple efficiency peaks distributed across the constellation. This is achieved by partitioning the I and Q amplitude codes such that each half of the code is applied to a separate inverter and capacitor array as shown in FIG. 4. Allocation of the digital amplitude codes to different branches of inverter and capacitor arrays of the ScPa, the system enables distinct branches to operate closer to their optimal power efficiency point more frequently throughout the signal space. For example, the best allocation is always to enable or activate all the inverters in the first branch of inverter and capacitor arrays before enabling or activating the other branches. The constellation points highlighted in FIG. 5 correspond to the amplitude combinations where power efficiency peaks occur, illustrating the benefit of this code allocation technique in maximizing energy efficiency across a broader range of modulation states. This approach supports improved performance for high-PAPR modulation schemes common in modern communication systems.

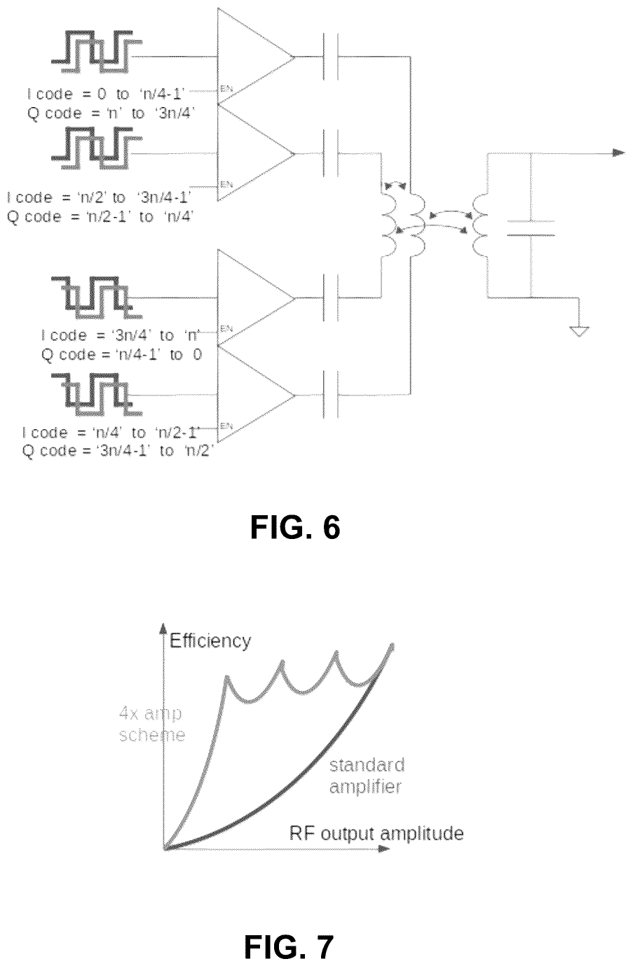

To further extend operating efficiency, each inverter and capacitor array can be subdivided into two or four independent sessions, forming four or eight separate branches. FIG. 6 illustrates an embodiment of a ScPa employing four parallel branches of inverter and capacitor arrays, each independently controlled by segments of the I and Q amplitude codes. These four branches of inverter and capacitor arrays can be efficiently combined by forming the series resonant balun primary from two tightly coupled inductors. The amplitude codes controlling the ScPa are segmented in FIG. 6, for example, by applying one-quarter interval of the I and Q amplitude codes to each respective branch, the system enables each inverter and capacitor array to operate within its most efficient range. As a result, different branches sequentially activate across the RF output amplitude range, producing multiple distinct efficiency peaks. This approach significantly improves overall power efficiency, especially for high-PAPR, by maintaining each branch near its optimal operating point for a greater portion of the time. Despite a modest increase in transformer complexity, the overall size remains within practical integration limits. If the coupling factor between the two primaries approaches unity, the resonant response of the power amplifier remains effectively unchanged, though a slight increase in unit capacitance may be required. This design also avoids large impedance mismatches, as the output impedance of each array remains effectively constant across gain levels.

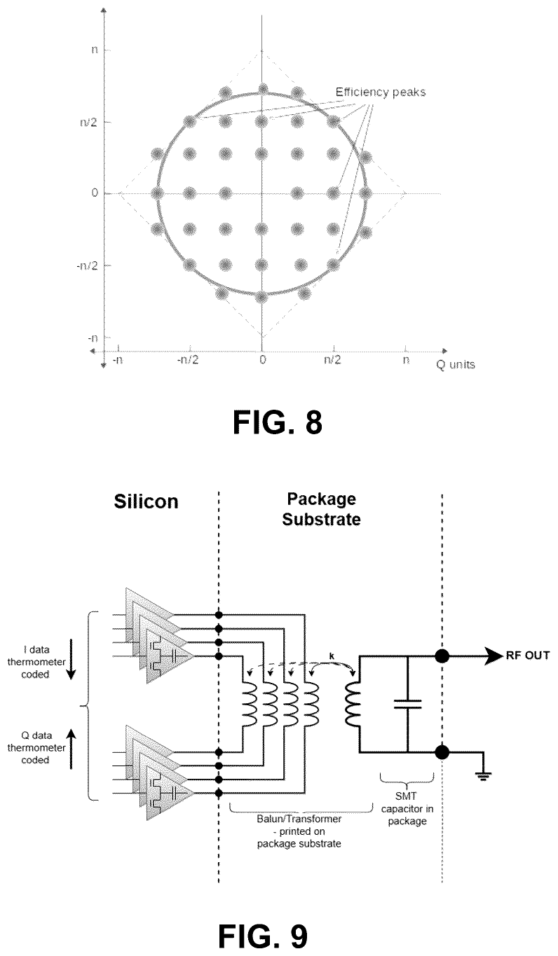

As depicted in FIG. 7, the four branches configuration shown in FIG. 6 enables four efficiency peaks across the output amplitude range. Maximum efficiency can be achieved at amplitude settings of ¼ (−12 dB), ½ (−6 dB), ¾ (−2.5 dB), and 1 (0 dB). In Cartesian systems, this results in an increased number of high-efficiency points throughout the output constellation of a cartesian system as shown in FIG. 8.

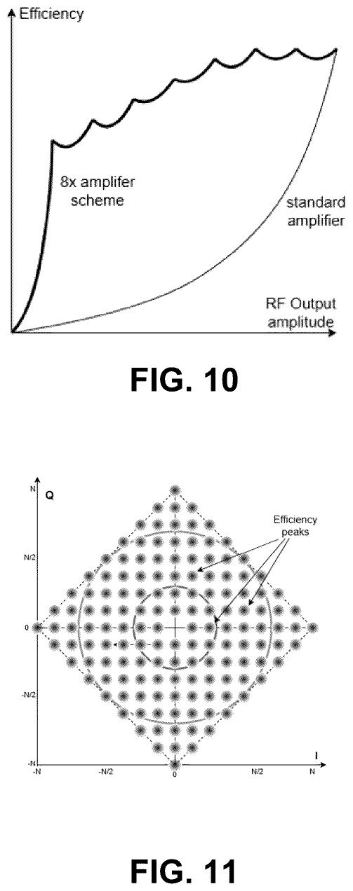

FIG. 9 illustrates an embodiment of a ScPa employing eight parallel branches of inverter and capacitor arrays, each independently controlled by segments of the I and Q amplitude codes. The eight branches of inverter and capacitor arrays can be efficiently combined by forming the series resonant balun primary from four tightly coupled inductors. The amplitude codes controlling the ScPa are segmented, for example, by applying one-eighth interval of the I and Q amplitude codes to each respective branch, each inverter and capacitor array can operate within its most efficient range. These eight branches sequentially activate across the RF output amplitude range, producing multiple distinct efficiency peaks. The goal of this approach is to ensure that each branch remains near its peak efficiency point for as much of the operating cycle as possible. FIG. 10 illustrates eight efficiency peaks across the output amplitude range when the eight branches configuration shown in FIG. 9 is employed. Maximum efficiency can be achieved at amplitude settings of ⅛ (−18 dB), ¼ (−12 dB), ⅜ (−8.5 dB), ½ (−6 dB), ⅝ (−4.1 dB), ¾ (−2.5 dB), ⅞ (−1.2 dB) and 1 (0 dB). This results in a further increased number of high-efficiency points for various I and Q combinations. FIG. 11 illustrates the high-efficiency points throughout the output constellation of the cartesian system for an eight branches ScPa.

Embodiments of the invention make the cartesian application of the system more feasible. The invention also allows for scalable extension to any number of branches through additional coupled transformer primaries. The increasing branches require more coupled transformer primaries, and the practical topology of achieving this is typically the technical limitation. To the extent that the transformer is not perfectly balanced between its multiple inputs, the combination will only exhibit a small linear gain differences between each combined amplifier, which is an issue far less problematic than the complicated digital pre-distortion techniques often required in other integrated PA implementations.

Finally, a comparison of power efficiency across different embodiments of the invention reveals a clear trend: as the number of independently driven branches increases, overall efficiency improves and the range of high-efficiency operation expands. A traditional differential drive ScPa exhibits the lowest efficiency, and introducing two independently driven branches with a single transformer primary yields a notable improvement. Further enhancement is achieved with a dual-primary, four-branch arrangement, and a higher efficiency is observed in a design with four transformer primaries and eight independently controlled branches. These results confirm that scaling the number of amplifier branches enables more frequent operation near each branch's optimal efficiency point, thereby significantly improving the system's performance across a broader output power range.

Although the invention is illustrated and described herein with reference to specific embodiments, the invention is not intended to be limited to the details shown. Rather, various modifications may be made in the details within the scope and range of equivalents of the claims and without departing from the invention. It is to be understood that the above description is illustrative of the invention and is not to be construed as limiting the invention. Various modifications, applications and/or combinations of the embodiments may occur to those skilled in the art without departing from the scope of the invention as defined by the claims. Well-known circuits, processes, algorithms, structures, and techniques may be shown without unnecessary detail to avoid obscuring the aspects.

To clearly illustrate the interchangeability of hardware and software, various illustrative components, blocks, modules, engines, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present application.

What is claimed is:

1. A Switch capacitor Power amplifier (ScPa), comprising:
at least two inverter and capacitor arrays, configured to be driven by a respective digital clock signal and a digital amplitude control signal, wherein each inverter drives a unit capacitor in the inverter and capacitor arrays; and
a transformer having a primary coil connected to the inverter and capacitor arrays and a secondary coil configured to deliver a Radio Frequency (RF) output signal;
wherein each inverter and capacitor array is selectively activated based on the digital amplitude control signal, such that all inverters of a first inverter and capacitor array are activated before any of the inverters of a second inverter and capacitor array.

2. The ScPa of claim 1, wherein the transformer is configured as a series resonant balun primary from two tightly coupled inductors.

3. The ScPa of claim 1, wherein the transformer primary inherently performs signal combination for the at least two inverter and capacitor arrays without requiring an external output combiner.

4. The ScPa of claim 1, wherein the inverter and capacitor arrays are activated in stages, such that the first inverter and capacitor array is fully driven before the second inverter and capacitor array is progressively enabled, producing multiple efficiency peaks over an RF output amplitude range.

5. The ScPa of claim 1, wherein the digital amplitude control signal comprises digital amplitude codes corresponding to In-phase (I) and Quadrature (Q) components, and the ScPa is configured to operate in a cartesian system.

6. The ScPa of claim 5, wherein a lower half of the digital amplitude codes corresponding to I component is applied to the first inverter and capacitor array, and a lower half of the digital amplitude codes corresponding to Q component is applied to the second inverter and capacitor array, with upper halves of the respective digital amplitude codes cross applied to the opposite array.

7. The ScPa of claim 5, wherein each inverter and capacitor array is subdivided into two or four independent sections, forming multiple separate branches, each branch is independently controlled by segments of the digital amplitude codes corresponding to the I and Q components.

8. The ScPa of claim 1, wherein each inverter and capacitor array is controlled independently to allow subsequential activation within the array.

9. The ScPa of claim 1, wherein four inverter and capacitor arrays are coupled via a dual-primary transformer composed of tightly coupled inductors, wherein each inverter and capacitor array corresponds to one-quarter of an amplitude code range for the digital amplitude control signal.

10. The ScPa of claim 9, wherein maximum power efficiency is achieved at amplitude settings corresponding to ¼, ½, ¾, and 1.

11. The ScPa of claim 1, wherein eight inverter and capacitor arrays are coupled via a quadruple-primary transformer composed of tightly coupled inductors, wherein each inverter and capacitor array corresponds to one-eighth of an amplitude code range for the digital amplitude control signal.

12. The ScPa of claim 11, wherein maximum power efficiency is achieved at amplitude settings corresponding to ⅛, ¼, ⅜, ½, ⅝, ¾, ⅞ and 1.

13. The ScPa of claim 1, wherein each inverter and capacitor array forms a capacitive voltage divider, and an amplitude of the RF output signal is proportional to the number of active inverters.

14. The ScPa of claim 1, wherein the inverter and capacitor arrays form a series resonant circuit with the transformer primary, tuned to a desired operating frequency.

15. The ScPa of claim 14, wherein the ScPa generates high currents at the desired operating frequency and attenuates unwanted RF harmonics created by the digital clock signal.

16. The ScPa of claim 15, wherein the high currents induced in the primary coil of the transformer is coupled to the secondary coil, and the high currents undergo impedance transformation.

17. The ScPa of claim 1, wherein inactive inverters in each inverter and capacitor array maintain impedance matching as the activated inverters.

18. The ScPa of claim 1, wherein the RF output signal is a single-ended signal suitable for directly driving a transmitting antenna.

19. The ScPa of claim 1, wherein independent drive signals are applied to each end of the primary coil, allowing each of the inverter and capacitor arrays to function as a separate amplifier branch.
